(19) United States
(12) Patent Application Publication
(10) Pub. No.: US 2013/0126228 A1
(43) Pub. Date: May 23, 2013

(54) Radio Frequency Identification Protective Liners for Clothing, Bags and Carrying Gear

(71) Applicant: Marie S. Jordan, Scranton, PA (US)

(72) Inventor: Marie S. Jordan, Scranton, PA (US)

(21) Appl. No.: 13/671,036

(22) Filed: Nov. 7, 2012

Related U.S. Application Data
(60) Provisional application No. 61/629,408, filed on Nov. 18, 2011.

(51) Int. Cl. H05K 5/02

(52) U.S. Cl. CPC H05K 5/02
USPC 174/378

(57) ABSTRACT

A carrying apparatus for carrying and shielding portable wireless transponders. A flexible, thin liner capable of blocking electromagnetic radiation is attached to the interior of a carrying apparatus such as a purse, pocket or wallet. By placing portable wireless transponder into the apparatus, the transponder is shielded from being read by an RFID base station.

### CROSS-REFERENCE TO RELATED APPLICATIONS

This application claims priority under 35 U.S.C. §119(e)(1) from U.S. Provisional Patent Application No. 61/629,408, filed on Nov. 18, 2011, for “Radio—frequency identification protective liners for clothing, bags & carrying gear,” by Marie Shannon Jordan, the disclosure of which is incorporated herein by reference.

### STATEMENT REGARDING FEDERALLY SPONSORED RESEARCH

Not Applicable.

### BACKGROUND

1. Field of Invention

The present invention relates to apparatuses used to shield portable wireless transponders. In particular, the present invention relates barriers that physically prohibit a reading device from reading the information stored in the transponder.

2. Description of Related Art

Portable wireless transponders employ RFID, Radio Frequency Identification, as the technology used to collect highway tolls, to serve as personal identification for access control, and to provide means for electronic information interchange, such as credit, etc. Passive RFID tags and wireless cards contain chips, (also known as computer chips, microchips, memory chips) which store identification and other information, such as credit card numbers, financial data, etc. Tags may be applied to items to identify the item in much the same way that bar codes are used. Information is retrieved from a transponder by an RFID base station or reader when the transponder is scanned with radio waves by the reader. The transponders may draw their power to function from the interrogation field supplied by the base station which reads or writes information to the transponder.

Examples of passive transponders are described in U.S. Pat. No. 3,713,148 issued to Cardullo and Parks. In its simplest form the RFID tag or device includes a circuit typically a silicon chip, although more than one chip may be used in the construction of the RFID device. The circuit is generally connected to an antenna. The RFID device or card may take on a variety of forms including that of a tag, a key fob, or a card. A battery may also be employed to extend the range of the device. It is also possible in principle to build devices that function as tags or wireless cards using electrical circuits including only resistors, capacitors and inductors as is well known by those skilled in the art. In some cases the circuit acts as an antenna and thus a separate antenna is not used.

Other transponders may contain a set of magnetic wires or a set of resonant devices, neither of which contain separate antennae to receive or send a signal upon interrogation but still have memory functions that may be interrogated in a manner similar to tags comprised of an antenna and chip. There are also non-electrical circuit memory devices, which are responsive to interrogation, that may be used to construct identification devices contained within cards and tags. Examples of such memory devices include magnetic devices, or wires such as those described in U.S. Pat. No. 5,538,803, and resonant structures such as are described in U.S. Pat. No. 5,563,583 and U.S. Pat. No. 5,581,257.

A major problem with a RFID transponder is that it could be commanded to send its information without the owner's consent or knowledge. This could release sensitive information that could potentially harm the owner if it was obtained by someone that was not authorized. The RFID transponder could expose that the owner is in possession of certain items that he/she wishes to remain private.

### SUMMARY

The present invention is designed to prevent unauthorized and unknowing access to RFID transponder information (e.g., provides protection against identity theft). In addition, the present invention provides protection against magnetic storms which could damage RFID transponders, rendering them useless. The invention comprises a thin sheet of a non-magnetic metallic material that envelopes the RFID transponder that the user wants to protect (e.g., transponding credit card, tablet computer, cellular telephone). In certain embodiments, the present invention comprises a liner that is attached inside a pocket on a piece of clothing or into a purse. This allows a user to place the RFID transponder inside the liner whenever he/she desires to protect it from unauthorized and unknowing access. When the user wants to use the RFID transponder, he/simply removes it from the liner. The present invention is therefore an inexpensive and easy to use solution for users who desire to protect their RFID transponders.

In other embodiments of the present invention, liner is fitted into the pocket and attached to the pocket by a temporary attachment means, such as Velcro or magnets, to hold the liner in position. The liner is therefore removable and transportable from one product to another, such as from a purse to a clothing pocket. The advantage of the liner removability is that it allows for the liner to be removed at security check points, as well as basic maintenance of clothing when washing and drying. Removability also allows the liner to maintain it's original protective qualities—washing the liner could lead to degradation of the material over time.

### BRIEF DESCRIPTION OF THE DRAWINGS

FIG. 1 is a perspective view of a handbag comprised of a liner that is consistent with the present invention.

FIG. 2 is a perspective view of a pants pocket comprised of a liner that is consistent with the present invention.

### DETAILED DESCRIPTION

A liner consistent with the present invention can be constructed of any known flexible, thin material capable of blocking electromagnetic radiation. Examples include textile fabrics which are coated with a metallic coating (e.g., silver, copper) after weaving or knitting of the fabric, textile fabrics which are primarily formed with natural fibers and include selectively placed conductive yarns, and textile fabrics formed from yarns containing metallic fibers or strands. Such material can be of any size and shaped by any known means such as cutting. The liner can be designed to fit all manner of known cavities used by individuals to store transponders, such as handbags, pockets, and wallets.

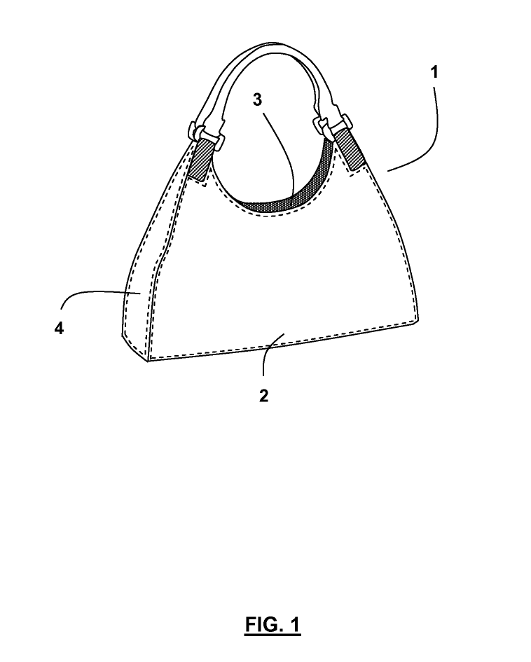

A preferred embodiment of the invention is illustrated in FIG. 1. Referring to FIG. 1, pieces of liner 2, 4 are shown sewn into the interior of a handbag 1. By closing the top 3 of the handbag 1, the liner 2, 4 surrounds whatever transponder has been placed inside of the handbag 1, thereby preventing a reader from reading the information emitted by the transponder.

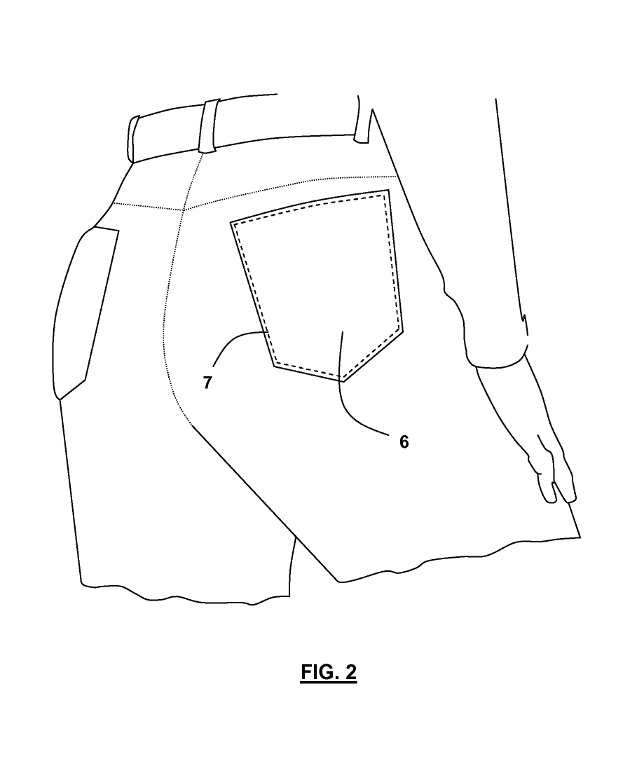

An alternative embodiment of the invention is illustrated in FIG. 2. As shown in FIG. 2, a liner 7 may be sewn into the pocket 6 of a piece of clothing. This allows a user to shield his/her transponder by placing it inside the lined pocket 6. Alternatively, liner is shaped to fit snugly into the pocket and attached to the pocket by a temporary attachment means, such as Velcro or magnets, to hold the liner in position.

While the invention has been described in conjunction with specific embodiments thereof it is evident that many alternatives, modifications and variations will be apparent to those skilled in the art. Accordingly, the preferred embodiments of the invention, as set forth herein, are intended to be illustrative, not limiting. Various changes may be made without departing from the true spirit and full scope of the invention, as defined in the following claims.

What is claimed is:

1. A carrying apparatus for carrying and shielding portable wireless transponders, comprising:
(a) a flexible, thin material capable of blocking electromagnetic radiation; and
(b) a cavity entirely lined with said flexible, thin material.

2. The carrying apparatus of claim 1, wherein said cavity comprises the interior of a handbag.

3. The carrying apparatus of claim 1, wherein said cavity comprises the interior of a pocket.

4. The carrying apparatus of claim 1, wherein said cavity comprises the interior of a wallet.

5. The carrying apparatus of claim 1, wherein said flexible, thin material is constructed of a magnetic material.

6. The carrying apparatus of claim 1, wherein said flexible, thin material is constructed of a metallic material.
